(19) United States
(12) Patent Application Publication
(10) Pub. No.: US 2024/0388261 A1
(43) Pub. Date: Nov. 21, 2024

(54) Amplifier circuit

(71) Applicant: REALTEK SEMICONDUCTOR CORPORATION, HSINCHU (TW)

(72) Inventor: SHIH-HSIUNG HUANG, Hsinchu (TW)

(21) Appl. No.: 18/654,027

(22) Filed: May 3, 2024

(30) Foreign Application Priority Data
May 15, 2023 (TW) 112117965

(51) Int. Cl. H03F 3/16

(52) U.S. Cl. CPC H03F 3/16; H03F 2200/366

(57) ABSTRACT

An amplifier circuit includes four transistors, eight switches, a first capacitor, and a second capacitor. When the first capacitor is charging, the four transistors is electrically connected to the second capacitor to perform amplification. When the second capacitor is charging, the four transistors is electrically connected to the first capacitor to perform amplification.

### BACKGROUND OF THE INVENTION

### 1. Field of the Invention

The present invention generally relates to amplifiers, and, more particularly, to dynamic amplifiers.

### 2. Description of Related Art

Because dynamic amplifiers do not require a current source to provide a fixed direct current (DC) current, there is no consumption of static current. Furthermore, because the current source requires a threshold voltage to conduct, and the process voltage for complementary metal-oxide-semiconductor (CMOS) technology is decreasing, this threshold voltage limits the swing of the amplifier's output signal. Based on the above reasons, amplifiers such as dynamic amplifiers that do not require static current and have relatively large output swings have recently been widely used in circuit systems. Therefore, improving the performance of dynamic amplifiers has become an important issue in this technical field.

### SUMMARY OF THE INVENTION

In view of the issues of the prior art, an object of the present invention is to provide an amplifier circuit, so as to make an improvement to the prior art.

According to one aspect of the present invention, an amplifier circuit is provided. The amplifier circuit includes a first input terminal, a second input terminal, a first output terminal, a second output terminal, a first node, a second node, a third node, a fourth node, a fifth node, and a sixth node. The amplifier circuit includes a first transistor, a second transistor, a third transistor, a fourth transistor, a first capacitor, a first switch, a second switch, a third switch, a fourth switch, a second capacitor, a fifth switch, a sixth switch, a seventh switch, and an eighth switch. The first transistor has a first terminal, a second terminal, and a first control terminal, wherein the first terminal is coupled to the first node, the second terminal is coupled to the second output terminal, and the first control terminal is coupled to the first input terminal. The second transistor has a third terminal, a fourth terminal, and a second control terminal, wherein the third terminal is coupled to the second node, the fourth terminal is coupled to the second output terminal, and the second control terminal is coupled to the first input terminal. The third transistor has a fifth terminal, a sixth terminal, and a third control terminal, wherein the fifth terminal is coupled to the first node, the sixth terminal is coupled to the first output terminal, and the third control terminal is coupled to the second input terminal. The fourth transistor has a seventh terminal, an eighth terminal, and a fourth control terminal, wherein the seventh terminal is coupled to the second node, the eighth terminal is coupled to the first output terminal, and the fourth control terminal is coupled to the second input terminal. The first capacitor has a ninth terminal and a tenth terminal, wherein the ninth terminal is coupled to the third node, and the tenth terminal is coupled to the fourth node. The first switch is coupled between the third node and a first reference voltage. The second switch is coupled between the fourth node and a second reference voltage. The third switch is coupled between the first node and the third node. The fourth switch is coupled between the second node and the fourth node. The second capacitor has an eleventh terminal and a twelfth terminal, wherein the eleventh terminal is coupled to the fifth node, and the twelfth terminal is coupled to the sixth node. The fifth switch is coupled between the fifth node and a third reference voltage. The sixth switch is coupled between the sixth node and a fourth reference voltage. The seventh switch is coupled between the first node and the fifth node. The eighth switch is coupled between the second node and the sixth node.

According to another aspect of the present invention, an amplifier circuit is provided. The amplifier circuit includes a first input terminal, a second input terminal, a first output terminal, a second output terminal, a first node, a second node, a third node, and a fourth node. The amplifier circuit includes a first transistor, a second transistor, a third transistor, a fourth transistor, a capacitor, a first switch, a second switch, a third switch, a fourth switch, a fifth switch, and a sixth switch. The first transistor has a first terminal, a second terminal, and a first control terminal, wherein the first terminal is coupled to the first node, the second terminal is coupled to the second output terminal, and the first control terminal is coupled to the first input terminal. The second transistor has a third terminal, a fourth terminal, and a second control terminal, wherein the third terminal is coupled to the second node, the fourth terminal is coupled to the second output terminal, and the second control terminal is coupled to the first input terminal. The third transistor has a fifth terminal, a sixth terminal, and a third control terminal, wherein the fifth terminal is coupled to the first node, the sixth terminal is coupled to the first output terminal, and the third control terminal is coupled to the second input terminal. The fourth transistor has a seventh terminal, an eighth terminal, and a fourth control terminal, wherein the seventh terminal is coupled to the second node, the eighth terminal is coupled to the first output terminal, and the fourth control terminal is coupled to the second input terminal. The capacitor has a ninth terminal and a tenth terminal, wherein the ninth terminal is coupled to the third node and the tenth terminal is coupled to the fourth node. The first switch is coupled between the third node and a first reference voltage. The second switch is coupled between the fourth node and a second reference voltage. The third switch is coupled between the first node and the third node. The fourth switch is coupled between the second node and the fourth node. The fifth switch is coupled between the third node and a third reference voltage. The sixth switch is coupled between the fourth node and a fourth reference voltage.

The technical means embodied in the embodiments of the present invention can solve at least one of the problems of the prior art. Therefore, compared to the prior art, the present invention can improve the performance and application range of the dynamic amplifier.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 is a circuit diagram of an amplifier circuit according to an embodiment of the present invention.

FIG. 2 shows waveforms of multiple clocks according to an embodiment of the present invention.

FIG. 3 is a circuit diagram of an amplifier circuit according to another embodiment of the present invention.

FIG. 4 is an example of the control signal of the present invention.

FIG. 5 is another example of the control signal of the present invention.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes an amplifier circuit. On account of that some or all elements of the amplifier circuit could be known, the detail of such elements is omitted provided that such detail has little to do with the features of this disclosure, and that this omission nowhere dissatisfies the specification and enablement requirements. A person having ordinary skill in the art can choose components or steps equivalent to those described in this specification to carry out the present invention, which means that the scope of this invention is not limited to the embodiments in the specification.

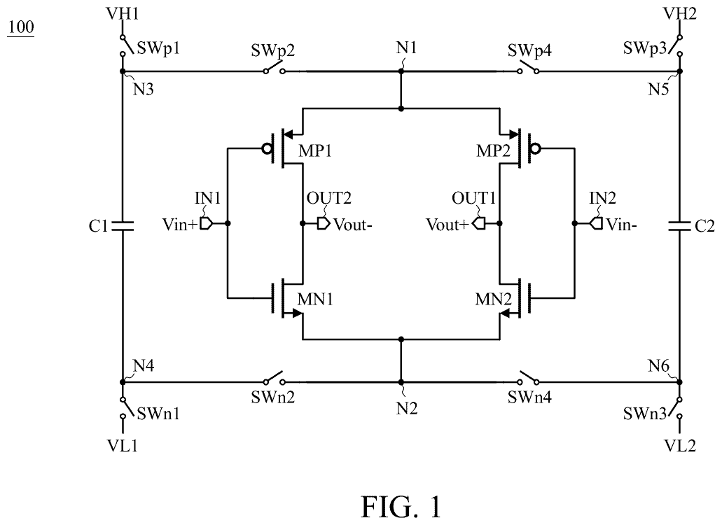

FIG. 1 is a circuit diagram of an amplifier circuit according to an embodiment of the present invention. The amplifier circuit 100 is a type of dynamic amplifier and has an input terminal IN1, an input terminal IN2, an output terminal OUT1, an output terminal OUT2, a node N1, a node N2, a node N3, a node N4, a node N5, and a node N6, and includes a transistor MP1, a transistor MN1, a transistor MP2, a transistor MN2, a capacitor C1, a capacitor C2, a switch SWp1, a switch SWn1, a switch SWp2, a switch SWn2, a switch SWp3, a switch SWn3, a switch SWp4, and a switch SWn4.

It should be noted that in order to focus the discussion below on the technical features of this disclosure, FIG. 1 omits the load capacitors coupled to the output terminal OUT1 and the output terminal OUT2. As people having ordinary skill in the art are familiar with the purpose of the load capacitors, further explanation is omitted for brevity.

The amplifier circuit 100 amplifies the input voltage Vin+ and the input voltage Vin− (inputted to the amplifier circuit 100 through the input terminal IN1 and the input terminal IN2 respectively) to generate the output voltage Vout+ and the output voltage Vout− (outputted through the output terminal OUT1 and the output terminal OUT2 respectively). The input voltage Vin+ and the input voltage Vin− are a pair of differential signals. The output voltage Vout+ and output voltage Vout− are a pair of differential signals.

The transistor MP1 is a P-channel Metal-Oxide-Semiconductor Field-Effect Transistor (hereinafter referred to as PMOS transistor). The source of the transistor MP1 is coupled or electrically connected to the node N1; the drain of the transistor MP1 is coupled or electrically connected to the output terminal OUT2; the gate (control terminal) of the transistor MP1 is coupled or electrically connected to the input terminal IN1.

The transistor MN1 is an N-channel Metal-Oxide-Semiconductor Field-Effect Transistor (hereinafter referred to as NMOS transistor). The source of the transistor MN1 is coupled or electrically connected to the node N2; the drain of the transistor MN1 is coupled or electrically connected to the output terminal OUT2; the gate of the transistor MN1 is coupled or electrically connected to the input terminal IN1.

The transistor MP2 is a PMOS transistor. The source of the transistor MP2 is coupled or electrically connected to the node N1; the drain of the transistor MP2 is coupled or electrically connected to the output terminal OUT1; the gate of the transistor MP2 is coupled or electrically connected to the input terminal IN2.

The transistor MN2 is an NMOS transistor. The source of the transistor MN2 is coupled or electrically connected to the node N2; the drain of the transistor MN2 is coupled or electrically connected to the output terminal OUT1; the gate of the transistor MN2 is coupled or electrically connected to the input terminal IN2.

One terminal of the switch SWp1 is coupled to the reference voltage VH1 (i.e., the switch SWp1 receives the reference voltage VH1); another terminal of the switch SWp1 is coupled or electrically connected to the node N3 (i.e., one terminal of the capacitor C1).

One terminal of the switch SWn1 is coupled to the reference voltage VL1 (i.e., the switch SWn1 receives the reference voltage VL1); another terminal of the switch SWn1 is coupled or electrically connected to the node N4 (i.e., the other terminal of the capacitor C1).

One terminal of the switch SWp2 is coupled or electrically connected to the node N1; another terminal of the switch SWp2 is coupled or electrically connected to the node N3.

One terminal of the switch SWn2 is coupled or electrically connected to the node N2; another terminal of the switch SWn2 is coupled or electrically connected to the node N4.

One terminal of the switch SWp3 is coupled to the reference voltage VH2 (i.e., the switch SWp3 receives the reference voltage VH2); another terminal of the switch SWp3 is coupled or electrically connected to the node N5.

One terminal of the switch SWn3 is coupled to the reference voltage VL2 (i.e., the switch SWn3 receives the reference voltage VL2); another terminal of the switch SWn3 is coupled or electrically connected to the node N6.

One terminal of the switch SWp4 is coupled or electrically connected to the node N1; another terminal of the switch SWp4 is coupled or electrically connected to the node N5.

One terminal of the switch SWn4 is coupled or electrically connected to the node N2; another terminal of the switch SWn4 is coupled or electrically connected to the node N6.

In some embodiments, the difference between the reference voltage VH1 and the reference voltage VL1 is equal to the difference between the reference voltage VH2 and the reference voltage VL2 (e.g., the reference voltage VH1 is equal to the reference voltage VH2 and the reference voltage VL1 is equal to the reference voltage VL2). In other embodiments, the difference between the reference voltage VH1 and the reference voltage VL1 is different from the difference between the reference voltage VH2 and the reference voltage VL2.

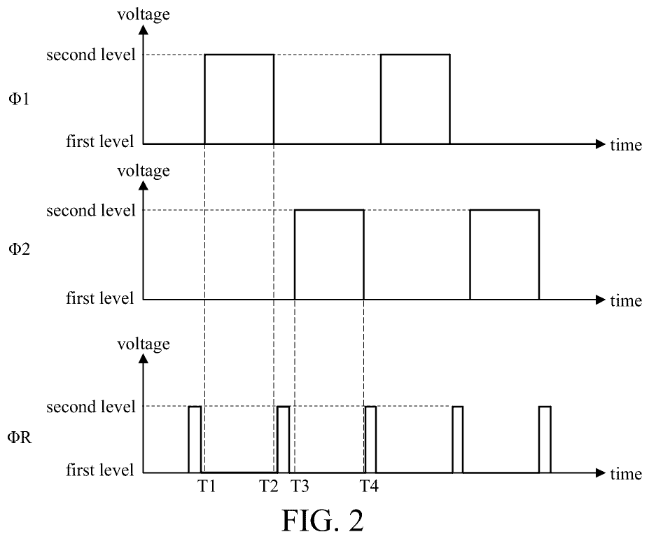

FIG. 2 shows waveforms of multiple clocks according to an embodiment of the present invention. The amplifier circuit 100 operates according to the clocks of FIG. 2. When the clock Φ1 is at the first level (low in FIG. 2's example, though not limited to this), the switch SWp1 and the switch SWn1 are turned on, and the switch SWp2 and the switch SWn2 are turned off. When the clock Φ1 is at the second level (high in FIG. 2's example, though not limited to this), the switch SWp1 and the switch SWn1 are turned off, and the switch SWp2 and the switch SWn2 are turned on. When the clock Φ2 is at the first level, the switch SWp3 and the switch SWn3 are turned on, and the switch SWp4 and the switch SWn4 are turned off. When the clock Φ2 is at the second level, the switch SWp3 and the switch SWn3 are turned off, and the switch SWp4 and the switch SWn4 are turned on. The clock ΦR is the reset clock. More specifically, when the clock ΦR is at the second level, the amplifier circuit 100 is reset (which includes, but it not limited to, resetting the terminal voltages of the transistor MP1, the transistor MN1, the transistor MP2, the transistor MN2, and the load capacitors). For brevity, the operational details of resetting the transistor MP1, the transistor MN1, the transistor MP2, the transistor MN2, and the load capacitors are omitted, as they are well known to people having ordinary skill in the art.

The clock Φ1 and the clock Φ2 are non-overlapping, meaning they are not at the high level or the low level at the same time. For instance, in FIG. 2, the clock @1 and the clock Φ2 are not at the high level at the same time. Therefore, both when the clock Φ1 is at the second level and when the clock Φ2 is at the second level, the amplifier circuit 100 can amplify the input signal (i.e., amplify the input voltage Vin+ and the input voltage Vin−) to generate an output signal (i.e., generate the output voltage Vout+ and the output voltage Vout−). In other words, the transistor MP1, the transistor MN1, the transistor MP2, and the transistor MN2 never idle. More specifically, while one of the capacitors, either C1 or C2, is being charged, the other capacitor provides the necessary power for the amplification operation to these four transistors.

Because the gain of the amplifier circuit 100 is proportional to the amount of charge on either the capacitor C1 or the capacitor C2 (the higher the amount of charge, the greater the gain), when the amount of charge Q1 on the capacitor C1 (=C1*(VH1−VL1)) is not equal to the amount of charge Q2 on the capacitor C2 (=C2*(VH2−VL2)), the gain A1 of the amplifier circuit 100 corresponding to the clock @1 (the K^{th} amplification operation, for example, between the time point T2 and the time point T1) is not equal to the gain A2 of the amplifier circuit 100 corresponding to the clock Φ2 (the (K+1)^{th} amplification operation, for example, between the time point T4 and the time point T3). Therefore, the amplifier circuit 100 can be used in various circuits.

For example, the amount of charge Q1 and the amount of charge Q2 can be designed to be different using one of the following approaches: (1) The capacitance value of the capacitor C1 is equal to the capacitance value of the capacitor C2 (i.e., C1=C2), but the difference between the reference voltage VH1 and the reference voltage VL1 is not equal to the difference between the reference voltage VH2 and the reference voltage VL2 (i.e., VH1−VL1/VH2−VL2); or (2) the difference between the reference voltage VH1 and the reference voltage VL1 is equal to the difference between the reference voltage VH2 and the reference voltage VL2 (i.e., VH1−VL1=VH2−VL2), but the capacitance value of the capacitor C1 is not equal to the capacitance value of the capacitor C2 (i.e., C1≠C2).

In some embodiments, the duration during which the clock Φ1 is at the second level (i.e., T2-T1) is not equal to the duration during which the clock Φ2 is at the second level (i.e., T4-T3). Even if C1 is equal to C2 and VH1−VL1 is equal to VH2−VL2, this design can make the amount of charge Q1 of the capacitor C1 not equal to the amount of charge Q2 of the capacitor C2, resulting in the gain A1 being not equal to the gain A2.

In other embodiments, the duration during which the clock Φ1 is at the second level (i.e., T2-T1) is equal to the duration during which the clock Φ2 is at the second level (i.e., T4-T3).

In some embodiments, the clock ΦR may be omitted. That is to say, the amplifier circuit 100 operates according to only the clock Φ1 and the clock Φ2.

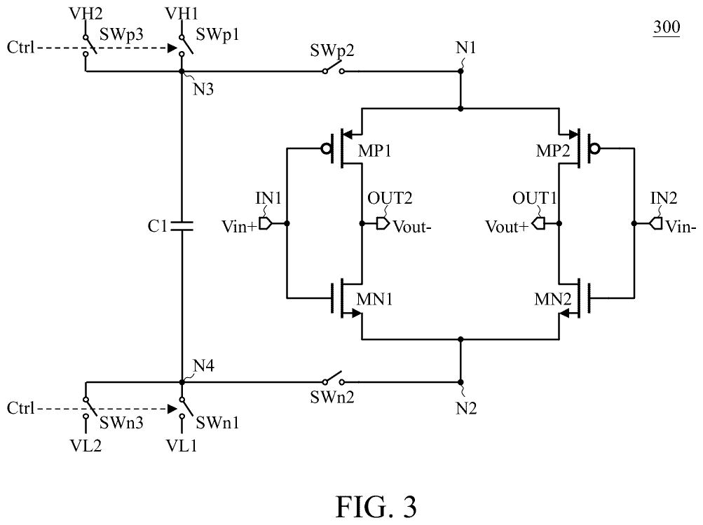

FIG. 3 is a circuit diagram of the amplifier circuit according to another embodiment of the present invention. The amplifier circuit 300, a type of dynamic amplifier, has an input terminal IN1, an input terminal IN2, an output terminal OUT1, an output terminal OUT2, a node N1, a node N2, a node N3, and a node N4, and includes a transistor MP1, a transistor MN1, a transistor MP2, a transistor MN2, a capacitor C1, a switch SWp1, a switch SWn1, a switch SWp2, a switch SWn2, a switch SWp3, and a switch SWn3.

The amplifier circuit 300 amplifies the input voltage Vin+ and the input voltage Vin− to generate the output voltage Vout+ and the output voltage Vout−.

The connections of the transistor MP1, the transistor MN1, the transistor MP2, the transistor MN2, the capacitor C1, the switch SWp1, the switch SWn1, the switch SWp2, and the switch SWn2 are identical to those shown in FIG. 1; details are omitted here for brevity.

One terminal of the switch SWp3 is coupled to the reference voltage VH2 (i.e., the switch SWp3 receives the reference voltage VH2); another terminal of the switch SWp3 is coupled or electrically connected to the node N3.

One terminal of the switch SWn3 is coupled to the reference voltage VL2 (i.e., the switch SWn3 receives the reference voltage VL2); another terminal of the switch SWn3 is coupled or electrically connected to the node N4.

The switch SWp1, the switch SWn1, the switch SWp2, the switch SWn2, the switch SWp3, and the switch SWn3 operate according to the clock Φ1 of FIG. 2. More specifically, when the clock Φ1 is at the first level, the switch SWp1 and the switch SWn1 are turned on (or the switch SWp3 and the switch SWn3 are turned on), and the switch SWp2 and the switch SWn2 are turned off. When the clock Φ1 is at the second level, the switch SWp1, the switch SWn1, the switch SWp3, and the switch SWn3 are turned off, and the switch SWp2 and the switch SWn2 are turned on. The amplifier circuit 300 is reset when the clock Φ1 is at the first level.

The amplifier circuit 300 couples or electrically connects both terminals of the capacitor C1 to the reference voltages VH1 and VL1 or the reference voltages VH2 and VL2 according to the control signal Ctrl. More specifically, when the switches SWp1 and SWn1 are enabled and the switches SWp3 and SWn3 are disabled, the two terminals of the capacitor C1 are respectively coupled or electrically connected to the reference voltage VH1 and the reference voltage VL1 when the clock Φ1 is at the first level. When the switches SWp1 and SWn1 are disabled and the switches SWp3 and SWn3 are enabled, the two terminals of the capacitor C1 are respectively coupled or electrically connected to the reference voltage VH2 and the reference voltage VL2 when the clock Φ1 is at the first level. It should be noted that the switch's state (on or off) is governed by the clock only when it is enabled. When disabled, the switch's state has no effect on the operation of the circuit.

In some embodiments, the difference between the reference voltage VH1 and the reference voltage VL1 is not equal to the difference between the reference voltage VH2 and the reference voltage VL2.

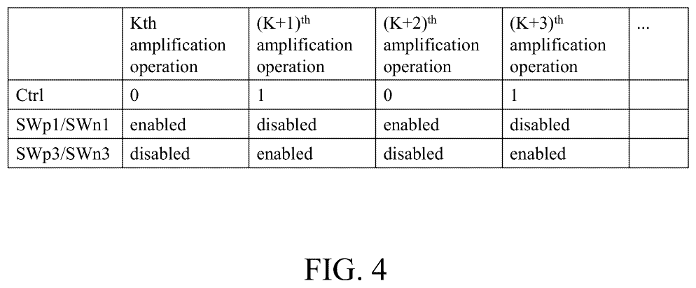

Reference is made to FIG. 4, which is an example of the control signal Ctrl of the present invention. When the value of the control signal Ctrl is 0, the switches SWp1 and SWn1 are enabled, and the switches SWp3 and SWn3 are disabled. When the value of the control signal Ctrl is 1, the switches SWp1 and SWn1 are disabled, and the switches SWp3 and SWn3 are enabled.

In the example of FIG. 4, the value of the control signal Ctrl is sequentially 0, 1, 0, 1, . . . in successive amplification operations of the amplifier circuit 300, wherein one amplification operation corresponds to one cycle of the clock Φ1. That is, the amplifier circuit 300 alternates its amplification operation between two sets of reference voltages: VH1 and VL1, and VH2 and VL2. In this context, the conduction of the switches SWp1 and SWn1 corresponds to either the odd-numbered or even-numbered outputs of the amplifier circuit 300, while the conduction of the switches SWp3 and SWn3 corresponds to the alternate sequence (even-numbered or odd-numbered) of the outputs.

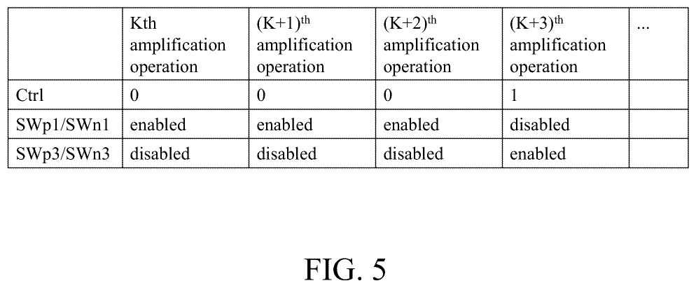

Reference is made to FIG. 5, which is another example of the control signal Ctrl of the present invention. In the example of FIG. 5, the value of the control signal Ctrl is sequentially 0, 0, 0, 1, . . . in successive amplification operations of the amplifier circuit 300. That is to say, the amplifier circuit 300 can successively perform amplification operations according to the reference voltages VH1 and VL1.

The amplifier circuit 100 and the amplifier circuit 300 are very flexible in operation. For example, successive amplification operations (i.e., the K^{th} amplification operation and the immediately following (K+1)^{th} amplification operation, K being a positive integer) may correspond to: (1) different gains (e.g., VH1−VL1 is not equal to VH2−VL2); (2) different input voltage ranges (i.e., the range of the input voltage (Vin+ and Vin−) of the K^{th} amplification operation is not equal to the range of the input voltage of the (K+1)^{th} amplification operation) (e.g., by selecting VH1 and VL1 or VH2 and VL2 to prevent the input voltage from being clipped); or (3) different input common-mode voltages (i.e., the input common-mode voltage of the K^{th} amplification operation is not equal to the input common-mode voltage of the (K+1)^{th} amplification operation, where the input common-mode voltage refers to the common-mode voltage of the input voltage Vin+ and the input voltage Vin−) (in this context, the average value of VH1 and VL1 and the average value of VH2 and VL2 may be made unequal to match different input common-mode voltages). This gives the amplifier circuit 100 and the amplifier circuit 300 great flexibility and a wide range of applications.

Note that the shape, size, and ratio of any element in the disclosed figures are exemplary for understanding, not for limiting the scope of this invention.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. An amplifier circuit having a first input terminal, a second input terminal, a first output terminal, a second output terminal, a first node, a second node, a third node, a fourth node, a fifth node, and a sixth node, the amplifier circuit comprising:
a first transistor having a first terminal, a second terminal, and a first control terminal, wherein the first terminal is coupled to the first node, the second terminal is coupled to the second output terminal, and the first control terminal is coupled to the first input terminal;
a second transistor having a third terminal, a fourth terminal, and a second control terminal, wherein the third terminal is coupled to the second node, the fourth terminal is coupled to the second output terminal, and the second control terminal is coupled to the first input terminal;
a third transistor having a fifth terminal, a sixth terminal, and a third control terminal, wherein the fifth terminal is coupled to the first node, the sixth terminal is coupled to the first output terminal, and the third control terminal is coupled to the second input terminal;
a fourth transistor having a seventh terminal, an eighth terminal, and a fourth control terminal, wherein the seventh terminal is coupled to the second node, the eighth terminal is coupled to the first output terminal, and the fourth control terminal is coupled to the second input terminal;
a first capacitor having a ninth terminal and a tenth terminal, wherein the ninth terminal is coupled to the third node and the tenth terminal is coupled to the fourth node;
a first switch coupled between the third node and a first reference voltage;
a second switch coupled between the fourth node and a second reference voltage;
a third switch coupled between the first node and the third node;
a fourth switch coupled between the second node and the fourth node;
a second capacitor having an eleventh terminal and a twelfth terminal, wherein the eleventh terminal is coupled to the fifth node, and the twelfth terminal is coupled to the sixth node;
a fifth switch coupled between the fifth node and a third reference voltage;
a sixth switch coupled between the sixth node and a fourth reference voltage;
a seventh switch coupled between the first node and the fifth node; and
an eighth switch coupled between the second node and the sixth node.

2. The amplifier circuit of claim 1, wherein the first switch, the second switch, the third switch, the fourth switch, the fifth switch, the sixth switch, the seventh switch, and the eighth switch operate according to a first clock and a second clock, and the first clock and the second clock are not at a second level at the same time; when the first clock is at a first level, the first switch and the second switch are turned on, and the third switch and the fourth switch are turned off; when the first clock is at the second level, the first switch and the second switch are turned off, and the third switch and the fourth switch are turned on; when the second clock is at the first level, the fifth switch and the sixth switch are turned on, and the seventh switch and the eighth switch are turned off; when the second clock is at the second level, the fifth switch and the sixth switch are turned off, and the seventh switch and the eighth switch are turned on.

3. The amplifier circuit of claim 2, wherein a duration during which the first clock is at the second level is not equal to a duration during which the second clock is at the second level.

4. The amplifier circuit of claim 1, wherein a difference between the first reference voltage and the second reference voltage is not equal to a difference between the third reference voltage and the fourth reference voltage.

5. The amplifier circuit of claim 1, wherein a capacitance value of the first capacitor is not equal to a capacitance value of the second capacitor.

6. An amplifier circuit having a first input terminal, a second input terminal, a first output terminal, a second output terminal, a first node, a second node, a third node, and a fourth node, the amplifier circuit comprising:
a first transistor having a first terminal, a second terminal, and a first control terminal, wherein the first terminal is coupled to the first node, the second terminal is coupled to the second output terminal, and the first control terminal is coupled to the first input terminal;
a second transistor having a third terminal, a fourth terminal, and a second control terminal, wherein the third terminal is coupled to the second node, the fourth terminal is coupled to the second output terminal, and the second control terminal is coupled to the first input terminal;
a third transistor having a fifth terminal, a sixth terminal, and a third control terminal, wherein the fifth terminal is coupled to the first node, the sixth terminal is coupled to the first output terminal, and the third control terminal is coupled to the second input terminal;
a fourth transistor having a seventh terminal, an eighth terminal, and a fourth control terminal, wherein the seventh terminal is coupled to the second node, the eighth terminal is coupled to the first output terminal, and the fourth control terminal is coupled to the second input terminal;
a capacitor having a ninth terminal and a tenth terminal, wherein the ninth terminal is coupled to the third node, and the tenth terminal is coupled to the fourth node;
a first switch coupled between the third node and a first reference voltage;
a second switch coupled between the fourth node and a second reference voltage;
a third switch coupled between the first node and the third node;
a fourth switch coupled between the second node and the fourth node;
a fifth switch coupled between the third node and a third reference voltage; and
a sixth switch coupled between the fourth node and a fourth reference voltage.

7. The amplifier circuit of claim 6, wherein the first switch, the second switch, the third switch, the fourth switch, the fifth switch, and the sixth switch operate according to a clock; when the clock is at a first level, the first switch and the second switch are turned on, and the third switch and the fourth switch are turned off; when the clock is at a second level, the first switch and the second switch are turned off, and the third switch and the fourth switch are turned on.

8. The amplifier circuit of claim 7, wherein the fifth switch and the sixth switch are disabled during one cycle of the clock.

9. The amplifier circuit of claim 6, wherein a difference between the first reference voltage and the second reference voltage is not equal to a difference between the third reference voltage and the fourth reference voltage.

10. The amplifier circuit of claim 6, wherein an average value of the first reference voltage and the second reference voltage is not equal to an average value of the third reference voltage and the fourth reference voltage.
